(19) United States
(12) Patent Application Publication
(10) Pub. No.: US 2026/0182028 A1
(43) Pub. Date: Jun. 25, 2026

(54) Array Substrate and Display Device

(71) Applicants: Beijing BOE Technology Development Co., Ltd., Beijing (CN); BOE Technology Group Co., Ltd., Beijing (CN)

(72) Inventors: Nianqi YAO, Beijing (CN); Hehe HU, Beijing (CN); Kun ZHAO, Beijing (CN); Guangcai YUAN, Beijing (CN); Ce NING, Beijing (CN); Zhengliang LI, Beijing (CN); Jie HUANG, Beijing (CN); Hui GUO, Beijing (CN)

(21) Appl. No.: 18/848,531

(22) PCT Filed: Sep. 22, 2023
(86) PCT No.: PCT/CN2023/120843

§ 371 Date: Sep. 19, 2024

(51) Int. Cl. H10D 86/40; G02F 1/1362; G02F 1/1368

(52) U.S. Cl. CPC H10D 86/441; G02F 1/136286; G02F 1/1368

(57) ABSTRACT

An array substrate and a display device are provided. The array substrate includes a base substrate (12), and at least one transistor (11), at least one data line (DL) and at least one first electrode (10) disposed on the base substrate (12). The at least one transistor (11) includes an active layer (17), the active layer (17) includes two or more sub-active layers arranged in a stack, the two or more sub-active layers includes a first sub-active layer, the first sub-active layer is closer to the base substrate (12) than other sub-active layers. The first sub-active layer includes a first channel region (170-1) and a first sub-region (171-1) and a third sub-region (172-3) located on two opposite sides of the first channel region (170-1). The data line (DL) is electrically connected with the first sub-region (171-1), and the first electrode (10) is electrically connected with the third sub-region (172-3).

### CROSS-REFERENCE TO RELATED APPLICATION

The present application is a U.S. National Phase Entry of International Application No. PCT/CN2023/120843 having an international filing date of Sep. 22, 2023, contents of which are incorporated into the present application by reference.

### TECHNICAL FIELD

The present disclosure relates to, but is not limited to, the field of display technologies, and in particular to an array substrate and a display device.

### BACKGROUND

Liquid crystal display (LCD) is a common display type at present. LCD screen is made of two pieces of polarizing material, with a liquid crystal solution between them. When an electric current passes through the liquid, crystals will be rearranged so that light cannot pass through them. Therefore, each crystal is like a shutter, which may both allow light to pass through and block light. At present, liquid crystal display (LCD) is developing towards the goals of being light, thin, short and small.

### SUMMARY

The following is a summary of subject matters described herein in detail. This summary is not intended to limit the protection scope of claims.

The present disclosure provides an array substrate and a display device.

In one aspect, an embodiment of the present disclosure provides an array substrate. The array substrate includes a base substrate, and at least one transistor, at least one data line and at least one first electrode disposed on the base substrate.

The at least one transistor includes an active layer, the active layer includes two or more sub-active layers arranged in a stack, the two or more sub-active layers include a first sub-active layer, and the first sub-active layer is closer to the base substrate than other sub-active layers. The first sub-active layer includes a first channel region and a first sub-region and a third sub-region located on two opposite sides of the first channel region. The data line is electrically connected with the first sub-region, and the first electrode is electrically connected with the third sub-region.

In an exemplary embodiment, each of the sub-active layers includes a top surface and a bottom surface disposed oppositely, and a side surface connecting the top surface and the bottom surface, and the top surface is farther away from the base substrate than the bottom surface. There is a slope angle between each side surface and a corresponding bottom surface.

An absolute value of a difference in slope angles of two adjacent sub-active layers is greater than or equal to 0 degree and less than or equal to 10 degrees.

In an exemplary embodiment, in a plane where the array substrate is located, a spacing between orthographic projection boundaries of the two adjacent side surfaces is zero.

In an exemplary embodiment, each of the sub-active layers includes a top surface and a bottom surface disposed oppositely, and a side surface connecting the top surface and the bottom surface. The active layer further includes a second sub-active layer and a third sub-active layer arranged in a stack, and the third sub-active layer is farther away from the first sub-active layer than the second sub-active layer.

The first sub-active layer has a first side surface and there is a first slope angle between the first side surface and an auxiliary plane parallel to a plane where the base substrate is located, the second sub-active layer has a second side surface and there is a second slope angle between the second side surface and the auxiliary plane, and the third sub-active layer has a third side surface and there is a third slope angle between the third side surface and the auxiliary plane.

The first slope angle is the same as the third slope angle and is not the same as the second slope angle.

In an exemplary embodiment, the first slope angle is greater than the second slope angle.

In an exemplary embodiment, the first slope angle ranges from 40 degrees to 50 degrees, and the second slope angle ranges from 20 degrees to 30 degrees.

In an exemplary embodiment, a spacing between orthographic projection boundaries of two adjacent side surfaces on the base substrate is zero.

In an exemplary embodiment, a spacing between orthographic projection boundaries of at least one set of two adjacent side surfaces on the base substrate is greater than zero and less than or equal to 20 nanometers.

In an exemplary embodiment, the active layer includes a top surface and a bottom surface disposed oppositely, and a side surface connecting the top surface and the bottom surface, and the top surface is farther away from the base substrate than the bottom surface. At least a part region of the side surface is an arc surface.

In an exemplary embodiment, at least one parameter of two adjacent sub-active layers is different, and the parameter includes at least one of material, metal doping amount, thickness, oxygen content, oxygen partial pressure, and crystalline state.

In an exemplary embodiment, an oxygen content of the first sub-active layer is greater than an oxygen content of a sub-active layer adjacent to the first sub-active layer.

In an exemplary embodiment, a material of the active layer includes a metal oxide semiconductor material.

In an exemplary embodiment, a material of the sub-active layers includes at least two of indium, gallium, and zinc elements; a doping amount of indium is greater than a doping amount of gallium, and the doping amount of indium is greater than a doping amount of zinc.

In an exemplary embodiment, the array substrate further includes a first conductive layer located on a side of the base substrate, and the first conductive layer is located between the base substrate and the active layer. The first conductive layer includes at least one data line.

In an exemplary embodiment, the array substrate further includes a connection electrode through which the data line is electrically connected with the first sub-region. The connection electrode and the active layer form an integrated structure connected with each other.

In an exemplary embodiment, the array substrate further includes a second conductive layer located on a side of the active layer away from the base substrate; the second conductive layer includes a gate electrode of the transistor.

The array substrate further includes a connection electrode, and the data line and the first sub-region are electrically connected through the connection electrode. The connection electrode and the gate electrode are in a same layer structure.

In an exemplary embodiment, the array substrate further includes a second conductive layer and a third conductive layer sequentially disposed and located on a side of the first conductive layer away from the base substrate. The array substrate further includes a first insulation layer located between the first conductive layer and the active layer, a second insulation layer located between the active layer and the second conductive layer, and a third insulation layer located between the second conductive layer and the third conductive layer. The third insulation layer is provided with at least one via, and the via exposes a part of a surface of the data line and the active layer.

The array substrate further includes a connection electrode, the data line and the first sub-region are electrically connected through the connection electrode; the third conductive layer includes the connection electrode, and a part of the connection electrode is located in the via.

In an exemplary embodiment, the first electrode and the active layer form an integrated structure connected with each other.

In another aspect, an embodiment of the present disclosure provides a display device. The display device includes the array substrate according to any one of the above embodiments, an opposed substrate and a liquid crystal layer. The array substrate is disposed opposite to the opposed substrate, and the liquid crystal layer is located between the array substrate and the opposed substrate.

Other aspects of the present disclosure may be comprehended after the drawings and the detailed description are read and understood.

### BRIEF DESCRIPTION OF DRAWINGS

Accompanying drawings are intended to provide further understanding of technical solutions of the present disclosure and form a part of the specification, and are used to explain the technical solutions of the present disclosure together with embodiments of the present disclosure, but do not form limitations on the technical solutions of the present disclosure. Shapes and sizes of one or more components in the drawings do not reflect actual scales, and are only intended to schematically describe contents of the present disclosure.

FIG. 1 is a schematic front view of an array substrate according to an embodiment of the present disclosure.

FIG. 2 is a first schematic cross-sectional view of an array substrate according to an embodiment of the present disclosure.

FIG. 3A is a partial enlarged schematic view of an active layer according to an embodiment of the present disclosure.

FIG. 3B is a partial enlarged schematic view of an active layer according to another embodiment of the present disclosure.

FIG. 3C is a partial enlarged schematic view of an active layer according to yet another embodiment of the present disclosure.

FIG. 3D is a partial enlarged schematic view of an active layer according to still yet another embodiment of the present disclosure.

FIG. 4 is a diagram showing a relationship between an oxygen content and a damage amount of an active layer of an array substrate according to an embodiment of the present disclosure.

FIG. 5 is a bar diagram showing a relationship between a crystalline state and an etching rate of a material of an active layer of an array substrate according to an embodiment of the present disclosure.

FIG. 6 is a bar diagram showing a relationship between an etching rate and active layers of different material of an array substrate according to an embodiment of the present disclosure.

FIGS. 7 and 8 are discrete curves of active layers of two different thicknesses of an array substrate according to an embodiment of the present disclosure, under the same number of pulses.

FIG. 9 is a curve of the light transmittance of first electrodes of different materials of an array substrate according to an embodiment of the present disclosure.

FIG. 10 is a curve of the light transmittance of first electrodes of different semiconductor materials of an array substrate according to an embodiment of the present disclosure.

FIG. 11 is a curve of the light transmittance of an active layer of an array substrate using different oxygen partial pressures according to an embodiment of the present disclosure.

FIG. 12 is a second schematic cross-sectional view of an array substrate according to an embodiment of the present disclosure.

FIG. 13A to FIG. 13F are schematic diagrams of a preparation process of an array substrate according to an embodiment of the present disclosure.

FIG. 14 is a schematic cross-sectional view of an array substrate according to another embodiment of the present disclosure.

FIG. 15A to FIG. 15E are schematic diagrams of a preparation process of an array substrate according to another embodiment of the present disclosure.

FIG. 16 is a first schematic cross-sectional view of an array substrate according to yet another embodiment of the present disclosure.

FIG. 17 is a second schematic cross-sectional view of an array substrate according to yet another embodiment of the present disclosure.

FIG. 18A to FIG. 18E are first schematic diagrams of a preparation process of an array substrate according to yet another embodiment of the present disclosure.

FIG. 19 is a third cross-sectional diagram of an array substrate according to yet another embodiment of the present disclosure.

FIG. 20 is a fourth schematic cross-sectional view of an array substrate according to yet another embodiment of the present disclosure.

FIG. 21A to FIG. 21G are second schematic diagrams of a preparation process of an array substrate according to yet another embodiment of the present disclosure.

FIG. 22 is a schematic cross-sectional view of a display device according to an embodiment of the present disclosure.

### REFERENCE NUMBERS

10—first electrode, 11—transistor, 12—base substrate, 13—first insulation layer, 14—second insulation layer, 15—third insulation layer, 16—light shielding block, 17—active layer, 170—channel region, 170-1—first channel region, 170-2—second channel region, 171—first region, 171-1—first sub-region, 171-2—second sub-region, 172—second region, 172-3—third sub-region, 172-4—fourth sub-region, 173—top surface, 174—bottom surface, 175—side surface, 175-1—first side surface, 175-2—second side surface, 175-3—third side surface, 18—gate electrode, 19—connection electrode, 20—common electrode, 21—common electrode line;

1—opposed substrate, 2—liquid crystal layer, 3—black matrix, 4—color film layer.

### DETAILED DESCRIPTION

Embodiments of the present disclosure will be described below with reference to the drawings in detail. Implementations may be implemented in a plurality of different forms. Those of ordinary skills in the art may easily understand such a fact that implementations and contents may be transformed into one or more forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals such as “first”, “second” and “third” in the present disclosure are set to avoid confusion between constituent elements, but not intended for restriction in quantity. In the present disclosure, “a plurality of/multiple” means two or more than two.

In the present disclosure, for convenience, wordings indicating orientation or positional relationship such as “middle”, “upper”, “lower”, “front”, “rear”, “vertical”, “horizontal”, “top”, “bottom”, “inner” and “outer” are employed to explain positional relationship between the constituent elements with reference to the accompanying drawings, they are employed for ease of description of the specification and simplification of the description only, but do not indicate or imply that the referred device or element must have a particular orientation, or is constructed and operate in a particular orientation, and therefore cannot be construed as limitations on the present disclosure. The positional relationships between the constituent elements are changed as appropriate based on directions according to which the constituent elements are described. Therefore, appropriate replacements based on situations are allowed, and the positional relationships are not limited to the wordings in the specification.

In the present disclosure, the terms “mounted”, “connected” and “connection” are to be understood broadly, unless otherwise expressly specified and defined. For example, a connection may be a fixed connection, or a detachable connection, or an integral connection; it may be a mechanical connection or an electrical connection; it may be a direct connection, or an indirect connection through middleware, or an internal communication between two elements. Those of ordinary skills in the art may understand meanings of the aforementioned terms in the present disclosure according to situations.

In the present disclosure, “electric connection” includes a case where constituent elements are connected through an element with a certain electrical action. An “element with a certain electrical action” is not particularly limited as long as electrical signals may be transmitted between the connected constituent elements. Examples of the “element with a certain electrical action” not only include electrodes and wirings, but also include switching elements such as transistors, resistors, inductors, capacitors, other elements with one or more functions, etc.

In the present disclosure, a transistor refers to an element including at least three terminals, i.e., a gate electrode, a drain electrode, and a source electrode. The transistor has a channel region between the drain electrode (drain electrode terminal, drain area, or drain) and the source electrode (source electrode terminal, source area, or source), and a current can flow through the drain electrode, the channel region and the source electrode. In the present disclosure, the channel region refers to a region through which a current mainly flows.

In the present disclosure, a first pole may be a drain electrode and a second pole may be a source electrode, or a first pole may be a source electrode and a second pole may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the present disclosure.

In the present disclosure, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 800 and below 100°, and thus may include a state in which the angle is above 850 and below 95°.

In the present disclosure, “film” and “layer” are interchangeable. For example, a “conductive layer” may be replaced with a “conductive film” sometimes. Similarly, an “insulation film” may be replaced with an “insulation layer” sometimes.

In the present disclosure, “about” or “approximately” refers to that a boundary is defined not so strictly and numerical values within process and measurement error ranges are allowed.

Triangle, rectangle, trapezoid, pentagon, hexagon or the like in the present disclosure are not strictly defined, and they may be approximate triangle, rectangle, trapezoid, pentagon, hexagon, etc. There may be some small deformations caused by tolerance, and there may be chamfer, arc edge, deformation, etc.

An embodiment of the present disclosure provides an array substrate. The array substrate includes a base substrate, and at least one transistor, at least one data line and at least one first electrode disposed on the base substrate.

The at least one transistor includes an active layer, the active layer includes two or more sub-active layers arranged in a stack, the two or more sub-active layers include a first sub-active layer, and the first sub-active layer is closer to the base substrate than other sub-active layers. The first sub-active layer includes a first channel region and a first sub-region and a third sub-region located on two opposite sides of the first channel region; the data line is electrically connected with the first sub-region, and the first electrode is electrically connected with the third sub-region.

In an embodiment of the present disclosure, by configuring the active layer to include two or more sub-active layers arranged in a stack, the etching resistance of the active layer can be improved, the reliability of the connection between the active layer and the data line can be improved, and the yield rate of the array substrate can be improved.

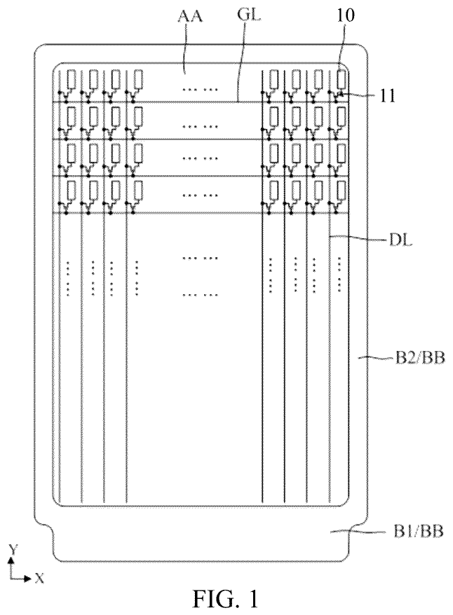

FIG. 1 is a schematic front view of an array substrate according to an embodiment of the present disclosure. As shown in FIG. 1, the array substrate may include a display area AA and a bezel area BB located around the display area AA. The bezel area BB may include a first bezel area B1 located on a side of the display area AA and a second bezel area B2 located on remaining sides of the display area AA. For example, the first bezel area B1 may include a lower bezel of the array substrate, and the second bezel area B2 may include an upper bezel, a left bezel, and a right bezel of the array substrate.

In an exemplary embodiment, as shown in FIG. 1, the display area AA may include a plurality of data lines DL and a plurality of gate lines GL disposed on a base substrate. The plurality of gate lines GL may extend along a first direction X, and are sequentially arranged along a second direction Y different from the first direction X. The plurality of data lines DL may extend along the second direction Y, and are sequentially arranged along the first direction X. The first direction X may intersect with the second direction Y. For example, the first direction X may be perpendicular to the second direction Y. The plurality of data lines DL and the plurality of gate lines GL may be located in different film layers. For example, the plurality of data lines DL may be located on a side of the plurality of gate lines GL close to the base substrate.

In an exemplary embodiment, as shown in FIG. 1, the plurality of data lines DL and the plurality of gate lines GL may intersect to form a plurality of sub-pixel regions. A region defined by adjacent data lines DL intersecting with adjacent gate lines GL may be a sub-pixel region. One sub-pixel may be correspondingly disposed in a sub-pixel region. The sub-pixel region may include an opening region and a non-opening region surrounding the opening region. The non-opening region may be a region that is shielded by a black matrix of an opposed substrate of the array substrate, and the opening region may be a region that is not shielded by the black matrix of the opposed substrate. The adjacent gate lines GL and the adjacent data lines DL may be all located in the non-opening region. The array substrate of the embodiment of the present disclosure may be configured to implement a display function, and the opening region of each sub-pixel region may be configured for display. The non-opening region surrounds the opening region, and does not perform displaying. However, the embodiments of the present disclosure are not limited to this. In some examples, the array substrate may be used for implementing other functions.

In an exemplary embodiment, the display area AA may include a plurality of pixel units disposed on the base substrate. At least one of the pixel units may include three sub-pixels (e.g. a first sub-pixel, a second sub-pixel, and a third sub-pixel arranged in sequence along the first direction X). The three sub-pixels of the pixel unit may be, for example, a blue sub-pixel, a red sub-pixel, and a green sub-pixel, and the three sub-pixels may be arranged sequentially in an order of the blue sub-pixel, the green sub-pixel, and the red sub-pixel. As shown in FIG. 1, at least one sub-pixel may include a first electrode 10 and a common electrode (not shown in FIG. 1), and orthographic projections of the first electrode 10 and the common electrode of the sub-pixel on the base substrate may overlap. For example, the first electrode 10 may be a pixel electrode. Common electrodes of a plurality of sub-pixels in the display area AA may be of an integral structure. For example, the common electrode may be located on a side of the first electrode 10 away from the base substrate. The sub-pixel may further include a transistor 11. The transistor 11 may be close to a position where the data line DL and the gate line GL intersect. The transistor 11 may include a gate electrode, a first pole, and a second pole. The gate electrode may be electrically connected with the gate line GL, the first pole of the transistor 11 may be electrically connected with the data line DL, and the second pole may be electrically connected with the first electrode 10 of a sub-pixel. The transistor 11 may be configured to supply a data signal transmitted by the data line DL to the first electrode 10 of the sub-pixel under control of the gate line GL.

A liquid crystal display device has a plurality of display modes, such as ADS (Advanced Super Dimension Switch) mode, TN (Twisted Nematic) mode, VA (Vertical Alignment) mode, and the like. In the ADS mode, both the first electrode and the common electrode are located on a side of the array substrate. In the TN mode and the VA mode, the first electrode and the common electrode are respectively disposed on two opposite sides of a liquid crystal layer, that is, the first electrode is located on a side of the array substrate, and the common electrode is located on a side of the opposed substrate.

The working principle of the ADS mode is that liquid crystal molecules are in a plane parallel to a glass substrate. When there is no voltage, light passes through a lower polarizing plate and then forms linearly polarized light parallel to a short axis of liquid crystal molecules. Since a direction of the polarized light cannot be rotated, it is absorbed by an upper polarizing plate and cannot be emitted. After applying a voltage, a transverse electric field is formed on the left and right sides of the liquid crystal, and the liquid crystal molecules are arranged in a direction of the electric field. After passing through the lower polarizing plate and the liquid crystal layer, the light is in an elliptically polarized state and may be emitted through the upper polarizing plate.

The working principle of TN mode is that in a voltage-free state, the liquid crystal molecules are twisted and aligned at 900 under the action of an alignment film, and light passes through the lower polarizing plate and the liquid crystal molecules and then is emitted from the upper polarizing plate. When a voltage is applied, most of the liquid crystal molecules are arranged vertically except the liquid crystal near matching films on upper and lower sides, and the light passing through the lower polarizing plate passes through the liquid crystal layer without deflection. Since it is parallel to a polarizing axis of the upper polarizing plate, the light is absorbed and cannot be emitted.

The working principle of VA mode is that liquid crystal molecules are aligned perpendicular to the glass substrate. When there is no voltage, light passes through the lower polarizing plate and then forms linearly polarized light parallel to a short axis of the liquid crystal molecules. Since a direction of the polarized light cannot be rotated, it is absorbed by the upper polarizing plate and cannot be emitted. After a voltage is applied, the liquid crystal molecules deflect along a direction of an electric field, and the light is in an elliptically polarized state after passing through the lower polarizing plate and the liquid crystal layer, and may be emitted through the upper polarizing plate.

The structure of the array substrate is introduced below by taking the ADS mode array substrate structure as an example.

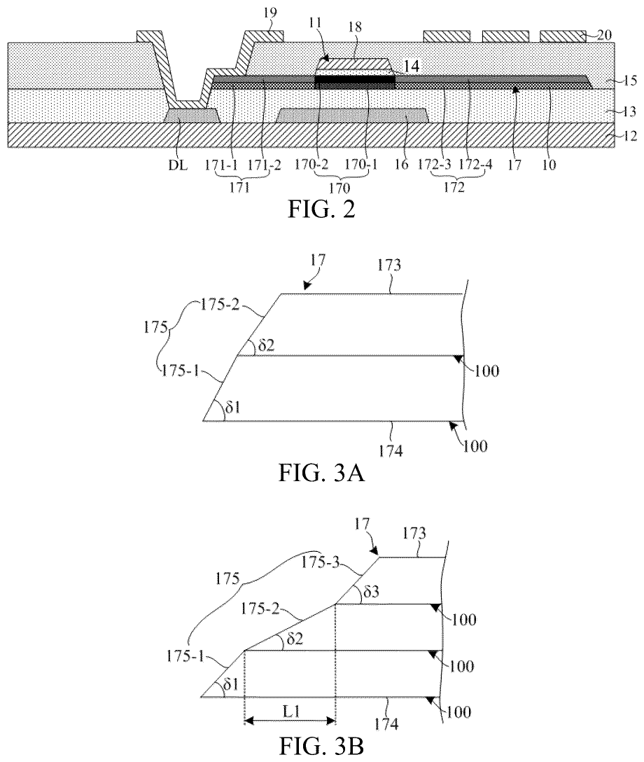

FIG. 2 is a first schematic cross-sectional view of an array substrate according to an embodiment of the present disclosure. As shown in FIG. 2, the array substrate may include a base substrate 12, and a first conductive layer, a semiconductor layer, a second conductive layer and a third conductive layer disposed on a side of the base substrate 12. The array substrate further includes a first insulation layer 13 located between the first conductive layer and the semiconductor layer, a second insulation layer 14 located between the semiconductor layer and the second conductive layer, and a third insulation layer 15 located between the second conductive layer and the third conductive layer. In the embodiment of the present disclosure, the first insulation layer may also be referred to as a buffer layer, the second insulation layer may also be referred to as a gate insulation (GI) layer, and the third insulation layer may also be referred to as a planarization (PLN) layer. The first conductive layer may include a data line DL and a light shielding block 16. The semiconductor layer may include an active layer 17 of a transistor 11, and a first electrode 10 and the active layer 17 may form an integrated structure connected with each other. The second conductive layer may include a gate electrode 18 of the transistor 11, and the active layer 17 may be electrically connected with the data line DL through a connection electrode 19. The third conductive layer may include a common electrode 20 and the connection electrode 19. In other examples, the data line DL may be located in a different film layer from the light shielding block 16. For example, the light shielding block may be located on a side of the data line close to the base substrate. In an embodiment of the present disclosure, by disposing the data line DL on a side of the transistor close to the base substrate 12, a capacitance between the data line DL and the first electrode 10 may be reduced, which may reduce a power consumption of the data line and improve performance of the array substrate.

In an exemplary embodiment, as shown in FIG. 2, the data line DL and the light shielding block 16 can be disposed in a same layer structure, which can simplify the preparation process of the array substrate, reduce the number of masks used, and reduce the production cost of the display substrate.

In an exemplary embodiment, the base substrate 12 may provide support for film layers in the array substrate other than the base substrate 12. For example, the base substrate 12 may be a transparent base substrate. For example, the base substrate 12 may be a rigid base substrate or a flexible base substrate. For example, a material of the rigid base substrate may include, but is not limited to, one or more of glass and quartz. A material of the flexible base substrate may include, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber. However, the embodiments of the present disclosure are not limited to this.

In an exemplary embodiment, the first conductive layer, the second conductive layer, and the third conductive layer may be made of metallic material(s), such as any one or more of molybdenum (Mo), aluminum (Al), copper (Cu) and titanium (Ti). Alternatively, the first conductive layer, the second conductive layer, and the third conductive layer may be made of an alloy material of metallic materials such as molybdenum (Mo), aluminum (Al), copper (Cu), and titanium (Ti), for example, an aluminum-neodymium alloy (AlNd) or a molybdenum-niobium alloy (MoNb), an molybdenum-nickel-titanium alloy (MoNiTi). The first conductive layer, the second conductive layer, and the third conductive layer may be a single-layer structure or a multilayer composite structure, such as Ti/Al/Ti or Mo/Nb/Cu or MoNiTi/Cu or MoNb/Cu/MoNiTi or MoNiTi/Cu/MoNiTi or the like.

In an exemplary embodiment, as shown in FIG. 2, an orthographic projection of the first insulation layer 13 on the array substrate may include an orthographic projection of the first conductive layer on the array substrate, and the first insulation layer 13 may prevent water and oxygen from eroding the data line DL and the light shielding block 16, thereby improving the reliability of use of the array substrate.

In an exemplary embodiment, a material of the first insulation layer 13 and the second insulation layer 14 may be an inorganic material. The inorganic material, for example, may include one or more of silicon oxide nitride (SiOₓN_{y}) or silicon nitride (SiNₓ) or silicon oxide (SiOₓ). The material of the first insulation layer 13 and the second insulation layer 14 may be an organic material. The organic material, for example, may include any one or more of epoxy resins, phenolic resins, urea-formaldehyde resins, melamine-formaldehyde resins, furan resins, silicone resins, polyester resins, polyamide resins, acrylic resins, polyurethane, vinyl resins, hydrocarbon resins, polyether resins, and the like. The first insulation layer 13 and the second insulation layer 14 may be a single-layer or a multi-layer or a composite layer.

In an exemplary embodiment, a material of the third insulation layer 15 may be an organic material. The organic material, for example, may include any one or more of epoxy resins, phenolic resins, urea-formaldehyde resins, melamine-formaldehyde resins, furan resins, silicone resins, polyester resins, polyamide resins, acrylic resins, polyurethane, vinyl resins, hydrocarbon resins, polyether resins, and the like. The third insulation layer 15 may be a single-layer or a multi-layer or a composite layer.

In an exemplary embodiment, as shown in FIG. 2, an orthographic projection of the active layer 17 on the array substrate may overlap with both orthographic projections of the data line DL and the light shielding block 16 on the array substrate. The active layer 17 may include a channel region 170, and a first region 171 and a second region 172 located on two opposite sides of the channel region 170. For example, in the process of preparing the array substrate, a conductivization processing may be performed on portions of the active layer 17 so that the portions of the active layer 17 form the first region 171 and the second region 172 respectively. The first region 171 of the active layer 17 may be used as a first pole of the transistor, and the second region 172 of the active layer 17 may be used as a second pole of the transistor. Conductivization process of the semiconductor layer is not limited in the embodiments of the present disclosure.

In an exemplary embodiment, as shown in FIG. 2, the active layer 17 may include two or more sub-active layers. For example, the active layer 17 may include two sub-active layers, or the active layer 17 may include three sub-active layers or the like. As shown in FIG. 2, taking the active layer 17 including two sub-active layers as an example, the two sub-active layers are designated as a first sub-active layer and a second sub-active layer, respectively, and the first sub-active layer is closer to the base substrate 12 than the second sub-active layer. As shown in FIG. 2, the channel region 170 may include a first channel region 170-1 and a second channel region 170-2. The first region 171 may include a first sub-region 171-1 and a second sub-region 171-2. The second region 172 may include a third sub-region 172-3 and a fourth sub-region 172-4. The first sub-active layer may include the first channel region 170-1 and the first sub-region 171-1 and the third sub-region 172-3 located on two opposite sides of the first channel region 170-1. The second sub-active layer may include the second channel region 170-2 and the second sub-region 171-2 and the fourth sub-region 172-4 located on two opposite sides of the second channel region 170-2.

In an exemplary embodiment, a material of the active layer 17 may include a metal oxide semiconductor material. The materials of the plurality of sub-active layers may be the same or different. The active layer may be made of one or more of indium gallium zinc oxide (IGZO), indium gallium tin oxide (IGTO), and indium tin zinc oxide (ITZO), indium gallium oxide (IGO), indium gallium zinc tin oxide (IGZTO), indium zinc oxide (IZO), zinc tin oxide (ZTO), indium-free metal oxide (In-free OS), rare earth doped oxide (Ln-OS). The material of the active layer may be in a non-crystalline, partially crystalline, monocrystalline or polycrystalline state. However, the metal oxide semiconductor materials are not limited in the present disclosure.

In an exemplary embodiment, oxygen contents of the plurality of sub-active layers are different. By way of example, an oxygen content of the first sub-active layer is greater than an oxygen content of the second sub-active layer.

In an exemplary embodiment, the crystalline states of the materials of the plurality of sub-active layer are different. By way of example, the material of the first sub-active layer is a crystalline material, and the material of the second sub-active layer is a non-crystalline material.

In an exemplary embodiment, metal doping amounts of the plurality of sub-active layers are different. By way of example, a metal doping amount of the first sub-active layer is greater than a metal doping amount of the second sub-active layer.

In an exemplary embodiment, the doping amounts of the same metal in two adjacent active layers are different.

In an exemplary embodiment, the doping amounts of a plurality of metals within the same sub-active layer are different. By way of example, the doping amount of indium (In) is greater than or equal to at least one of the doping amount of gallium (Ga) and the doping amount of zinc (Zn) in the same sub-active layer. By way of example, the doping amount of indium (In) is greater than the doping amount of gallium (Ga), and the doping amount of indium (In) is equal to the doping amount of zinc (Zn).

In an exemplary embodiment, the doping amount of indium (In) is greater than or equal to at least one of the doping amount of gallium (Ga) and the doping amount of zinc (Zn) in the sub-active layer close to the gate electrode 18. For example, the doping amount of indium (In) is greater than the doping amount of gallium (Ga), and the doping amount of indium (In) is greater than the doping amount of zinc (Zn), so that good conductivity of the sub-active layer can be ensured.

In an exemplary embodiment, a thickness of the sub-active layer may range from 200 angstroms to 1000 angstroms.

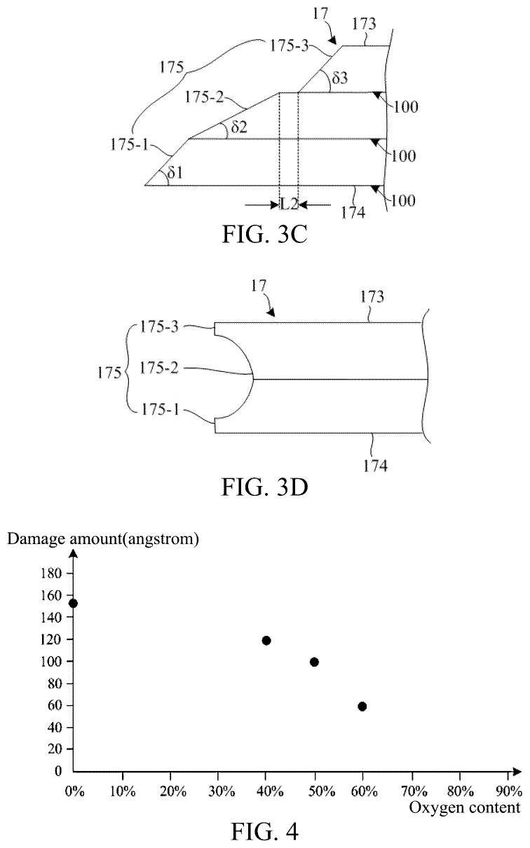

FIG. 3A is a partial enlarged schematic view of an active layer according to an embodiment of the present disclosure. As shown in FIG. 3A, the active layer 17 may include a top surface 173 and a bottom surface 174 disposed oppositely, and a side surface 175 connecting the top surface 173 and the bottom surface 174. The top surface 173 and the bottom surface 174 are disposed oppositely along a thickness direction of the array substrate, and the top surface 173 is farther away from the base substrate than the bottom surface 174. The side surface 175 may include a first side surface 175-1 and a second side surface 175-2 connected with each other, a first end of the first side surface 175-1 may be connected with the bottom surface 174, and a second end of the first side surface 175-1 may be connected with a first end of the second side surface 175-2. A second end of the second side surface 175-2 may be connected with the top surface 173. The first side surface 175-1 is located in the first sub-active layer, and the second side surface 175-2 is located in the second sub-active layer.

As shown in FIG. 3A, there is a first slope angle 61 between the first side surface 175-1 and a plane where the array substrate is located, and there is a second slope angle 62 between the second side surface 175-2 and the plane where the array substrate is located. An absolute value of a difference between the first slope angle 61 and the second slope angle 62 is greater than or equal to 0 degree, and less than or equal to 10 degrees. In an embodiment of the present disclosure, a plane parallel to the plane where the array substrate is located may be defined as an auxiliary plane, and the auxiliary plane is also parallel to the plane where the base substrate is located. In an embodiment of the present disclosure, the array substrate may include at least two auxiliary planes, which may be arranged sequentially along a direction perpendicular to the base substrate. In an embodiment of the present disclosure, the auxiliary plane is labeled 100.

In some possible embodiments, the absolute value of the difference between the first slope angle 61 and the second slope angle 62 is greater than 10 degrees.

FIG. 3B is a partial enlarged schematic view of an active layer according to another embodiment of the present disclosure. As shown in FIG. 3B, the active layer 17 may include a top surface 173 and a bottom surface 174 disposed oppositely, and a side surface 175 connecting the top surface 173 and the bottom surface 174. The top surface 173 and the bottom surface 174 are disposed oppositely along the thickness direction of the array substrate, and the top surface 173 is farther away from the base substrate than the bottom surface 174. The side surface 175 may include a first side surface 175-1, a second side surface 175-2, and a third side surface 175-3 connected with each other. A first end of the first side surface 175-1 may be connected with the bottom surface 174, a second end of the first side surface 175-1 may be connected with a first end of the second side surface 175-2, a second end of the second side surface 175-2 may be connected with a first end of the third side surface 175-3, and a second end of the third side surface 175-3 may be connected with the top surface 173. The first side surface 175-1 is located in the first sub-active layer, the second side surface 175-2 is located in the second sub-active layer, and the third side surface 175-3 is located in a third sub-active layer.

As shown in FIG. 3B, there is a first slope angle δ1 between the first side surface 175-1 and the plane where the array substrate is located, there is a second slope angle δ2 between the second side surface 175-2 and the plane where the array substrate is located, and there is a third slope angle δ3 between the third side surface 175-3 and the plane where the array substrate is located. At least two of the first slope angle δ1, the second slope angle δ2, and the third slope angle δ3 are the same. By way of example, the first slope angle δ1 may be equal to the third slope angle δ3, and may be greater than the second slope angle δ2. By way of example, the first slope angle δ1 may be 47 degrees, and the second slope angle δ2 may be 26 degrees. Alternatively, the first slope angle δ1, the second slope angle δ2, and the third slope angle δ3 may be the same slope angle.

In an exemplary embodiment, the first slope angle δ1 may be equal to the third slope angle δ3, the first slope angle δ1 has a range of 40 degrees to 50 degrees and the second slope angle δ2 has a range of 20 degrees to 30 degrees.

In an exemplary embodiment, as shown in FIG. 3B, an orthographic projection of the second side surface 175-2 on the array substrate does not overlap with an orthographic projection of the first side surface 175-1 on the array substrate, and an orthographic projection of the third side surface 175-3 on the array substrate does not overlap with an orthographic projection of the second side surface 175-2 on the array substrate. Alternatively, an orthographic projection of the second side surface 175-2 on the array substrate partially overlaps with an orthographic projection of the first side surface 175-1 on the array substrate, and an orthographic projection of the third side surface 175-3 on the array substrate partially overlaps with an orthographic projection of the second side surface 175-2 on the array substrate. In one example, the first side surface 175-1, the second side surface 175-2, and the third side surface 175-3 may be smoothly connected with each other to form a same plane along the thickness direction of the array substrate.

There is a spacing L1 between the orthographic projection of the third side surface 175-3 on the array substrate and the orthographic projection of the first side surface 175-1 on the array substrate, and the range of L1 may be greater than or equal to 1.0 nanometer and less than or equal to 50 nanometers.

In some possible embodiments, the first slope angle δ1, the second slope angle δ2, and the third slope angle δ3 are different.

FIG. 3C is a partial enlarged schematic view of an active layer according to yet another embodiment of the present disclosure. As shown in FIG. 3C, there is a spacing L2 between the orthographic projection of the third side surface 175-3 on the array substrate and the orthographic projection of the second side surface 175-2 on the array substrate, and the range of L2 may be greater than 0 nanometer and less than or equal to 20 nanometers.

FIG. 3D is a partial enlarged schematic view of an active layer according to yet another embodiment of the present disclosure. As shown in FIG. 3D, the active layer 17 may include a top surface 173 and a bottom surface 174 disposed oppositely, and a side surface 175 connecting the top surface 173 and the bottom surface 174. The top surface 173 and the bottom surface 174 are disposed oppositely along the thickness direction of the array substrate, and the top surface 173 is farther away from the base substrate than the bottom surface 174. The side surface 175 may include a first side surface 175-1, a second side surface 175-2, and a third side surface 175-3 connected with each other. A first end of the first side surface 175-1 may be connected with the bottom surface 174, a second end of the first side surface 175-1 may be connected with a first end of the second side surface 175-2, a second end of the second side surface 175-2 may be connected with a first end of the third side surface 175-3, and a second end of the third side surface 175-3 may be connected with the top surface 173. As shown in FIG. 3D, at least one of the first side surface 175-1, the second side surface 175-2, and the third side surface 175-3 may be an arc surface. As shown in FIG. 3D, the second side surface 175-2 may be an arc surface recessed towards the inside of the active layer 17. By way of example, the second side surface 175-2 may be a circular arc surface, and the first side surface 175-1 and the third side surface 175-3 may both be planar surfaces. Alternatively, the first side surface 175-1, the second side surface 175-2, and the third side surface 175-3 are all arc surfaces.

FIG. 4 is a diagram showing a relationship between an oxygen content and a damage amount of an active layer of an array substrate according to an embodiment of the present disclosure. In an embodiment of the present disclosure, the damage amount is defined as a thickness of etching material that can be removed per unit time, in angstrom. As shown in FIG. 4, which a diagram showing the relationship between the oxygen content and the damage amount of the IGZO semiconductor material, when the oxygen content of the IGZO semiconductor material is about 0, the damage amount of the active layer is about 150 angstroms. When the oxygen content of IGZO semiconductor material is about 40%, the damage amount of the active layer is about 120 angstroms. When the oxygen content of IGZO semiconductor material is about 50%, the damage amount of the active layer is about 100 angstroms. When the oxygen content of IGZO semiconductor material is about 60%, the damage amount of the active layer is about 60 angstroms. It can be seen that for IGZO semiconductor materials, increasing the oxygen content of the active layer semiconductor material can improve the etching resistance of the active layer, that is, with the increase of the oxygen content in the active layer semiconductor material, the damage amount gradually decreases.

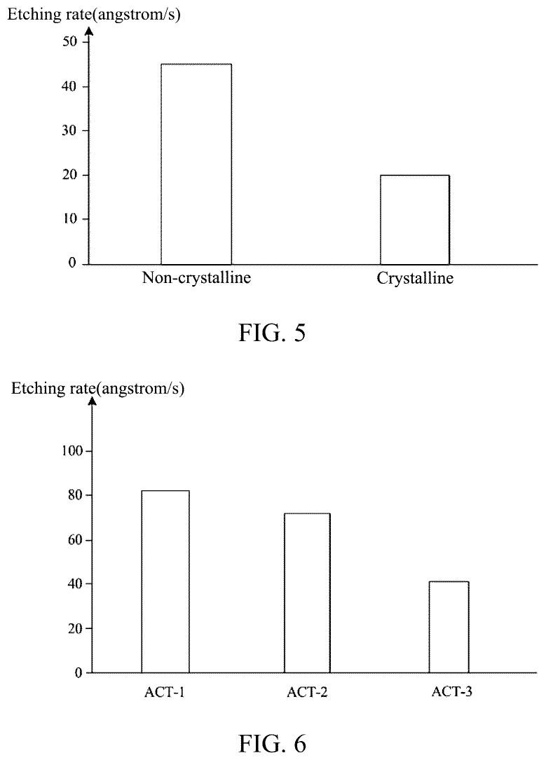

FIG. 5 is a bar diagram showing a relationship between a crystalline state and an etching rate of a material of an active layer of an array substrate according to an embodiment of the present disclosure. As shown in FIG. 5, taking the material of the active layer as an IGZO semiconductor material as an example, the etching rate of the IGZO semiconductor material in a crystalline state is about 20 angstroms per second, and the etching rate of the IGZO semiconductor material in a non-crystalline state is about 45 angstroms per second. The IGZO semiconductor material in the crystalline state has better etching resistance than the IGZO semiconductor material in the non-crystalline state.

FIG. 6 is a bar diagram showing a relationship between an etching rate and active layers of different materials of an array substrate according to an embodiment of the present disclosure. As shown in FIG. 6, the active layers of different materials have different etching rates. In ACT-2, the doping amount of indium (In) is equal to the doping amount of gallium (Ga) and equal to the doping amount of zinc (Zn). In ACT-1, the doping amount of indium (In) is less than 33.3% of the total doping amount of indium (In), gallium (Ga), and zinc (Zn). In ACT-3, the doping amount of indium (In) is more than 33.3% of the total doping amount of indium (In), gallium (Ga) and zinc (Zn).

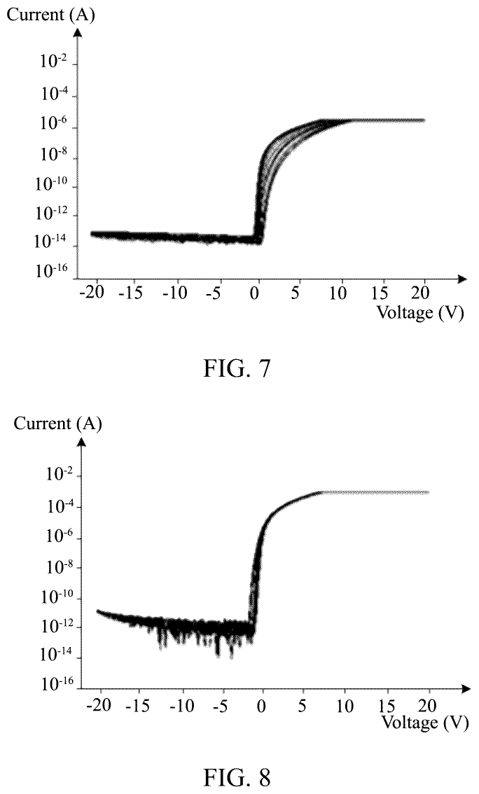

FIGS. 7 and 8 are discrete curves of two active layers of different thicknesses of an array substrate according to an embodiment of the present disclosure, under the same number of pulses. In FIG. 7, the material of the active layer is IGZO semiconductor material, and its thickness is 500 angstroms. In FIG. 8, the material of the active layer is IGZO semiconductor material, and its thickness is 700 angstroms. As can be seen from FIGS. 7 and 8, increasing the thickness of the active layer can improve the voltage and current resistance of the transistor.

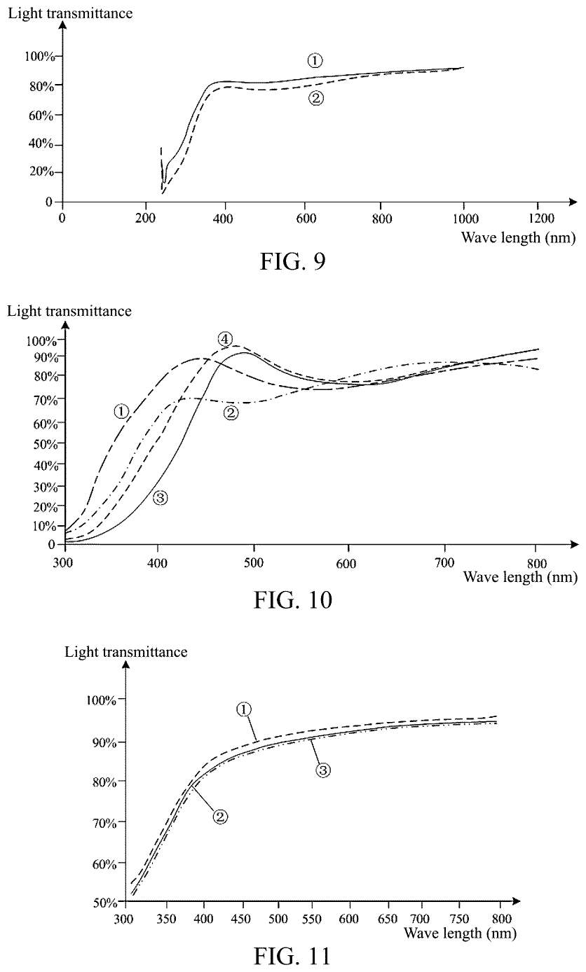

FIG. 9 is a curve of the light transmittance of first electrodes of different materials of an array substrate according to an embodiment of the present disclosure. As shown in FIG. 9, the curve D represents a graph of the light transmittance of the first electrode where the material of the first electrode is the same as the material of the active layer. The curve @represents a graph of the light transmittance of the first electrode where the material of the first electrode is a transparent conductive material which is exemplified as indium tin oxide (ITO). As can be seen from FIG. 9, the light transmittance of the first electrode using the material of the active layer is slightly improved compared to the light transmittance of the first electrode using the transparent conductive material.

FIG. 10 is a curve of the light transmittance of first electrodes of different semiconductor materials of an array substrate according to an embodiment of the present disclosure. As shown in FIG. 10, the curve \textcircled{1} represents that the material of the first electrode is IGZO, the curve \textcircled{2} represents that the material of the first electrode is IGTO (indium gallium tin oxide), the curve \textcircled{3} represents that the material of the first electrode is IGZYO (indium gallium zinc Y oxide), where Y represents tin doped, and the curve \textcircled{4} represents that the material of the first electrode is IZO (indium zinc oxide). As shown in FIG. 10, the thicknesses of different semiconductor materials are the same, and taking a thickness of 2000 angstroms as an example, the light transmittance of the first electrodes of different semiconductor materials is different for light of different wavebands. Using the semiconductor material for the material of the first electrode can improve the light transmittance of light of specific wavebands.

FIG. 11 is a curve of the light transmittance of an active layer of an array substrate using different oxygen partial pressures according to an embodiment of the present disclosure. As shown in FIG. 11, the curve \textcircled{1} represents that the partial pressure of oxygen for preparing the active layer is 0%, the curve \textcircled{2} represents that the partial pressure of oxygen for preparing the active layer is 20%, and the curve \textcircled{3} represents that the partial pressure of oxygen for preparing the active layer is 5%. As can be seen from FIG. 11, changing the partial pressure of oxygen for preparing the active layer can change the light transmittance of the active layer. In the integrated structure in which the first electrode and the active layer are connected with each other, the light transmittance of the first electrode can be changed by changing the partial pressure of oxygen for preparing the active layer.

FIG. 12 is a second schematic cross-sectional view of an array substrate according to an embodiment of the present disclosure. As shown in FIG. 12, the array substrate may include a base substrate 12, and a first conductive layer, a semiconductor layer, a second conductive layer and a third conductive layer disposed on a side of the base substrate 12. The array substrate further includes a first insulation layer 13 located between the first conductive layer and the semiconductor layer, a second insulation layer 14 located between the semiconductor layer and the second conductive layer, and a third insulation layer 15 located between the second conductive layer and the third conductive layer. The first conductive layer may include a data line DL and a light shielding block 16. The semiconductor layer may include an active layer 17 of a transistor 11, and a first electrode 10 and the active layer 17 may form an integrated structure connected with each other. The second conductive layer may include a gate electrode 18 of the transistor 11, and the active layer 17 may be electrically connected with the data line DL through a connection electrode 19. The third conductive layer may include a common electrode 20 and the connection electrode 19.

As shown in FIG. 12, the active layer 17 may include two or more sub-active layers. For example, the active layer 17 may include two sub-active layers, or the active layer 17 may include three sub-active layers or the like. As shown in FIG. 12, taking the active layer 17 including two sub-active layers as an example, the two sub-active layers are designated as a first sub-active layer and a second sub-active layer, respectively, and the first sub-active layer is closer to the base substrate 12 than the second sub-active layer. As shown in FIG. 12, the channel region 170 may include a first channel region 170-1 and a second channel region 170-2. The first region 171 may include a first sub-region 171-1 and a second sub-region 171-2. The second region 172 may include a third sub-region 172-3 and a fourth sub-region 172-4. The first sub-active layer may include the first channel region 170-1 and the first sub-region 171-1 and the third sub-region 172-3 located on two opposite sides of the first channel region 170-1. The second sub-active layer may include the second channel region 170-2 and the second sub-region 171-2 and the fourth sub-region 172-4 located on two opposite sides of the second channel region 170-2.

As shown in FIG. 12, an orthographic projection of the second sub-region 171-2 on the array substrate is within an orthographic projection of the first sub-region 171-1 on the array substrate, and the first sub-region 171-1 is connected with the data line DL through the connection electrode 19. In this exemplary embodiment, a part of the second sub-region 171-2 may function as a sacrificial layer during the preparation of the pattern of the third insulation layer 15, which may protect the first sub-region 171-1 from etching damage during the preparation of the pattern of the third insulation layer, may guarantee the connection reliability between the transistor and the data line DL, and may improve the yield of the array substrate.

A structure of an array substrate is described below by an example of a manufacturing process of the array substrate. A “patterning process” mentioned in the embodiments of the present disclosure includes a treatment such as photoresist coating, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a material on a base substrate by using deposition, coating, or another process. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. In the present disclosure, “A and B are in a same layer structure” means that A and B are formed through a same patterning process.

Taking the structure of the array substrate shown in FIG. 2 as an example, the manufacturing process of the array substrate may include the following steps.

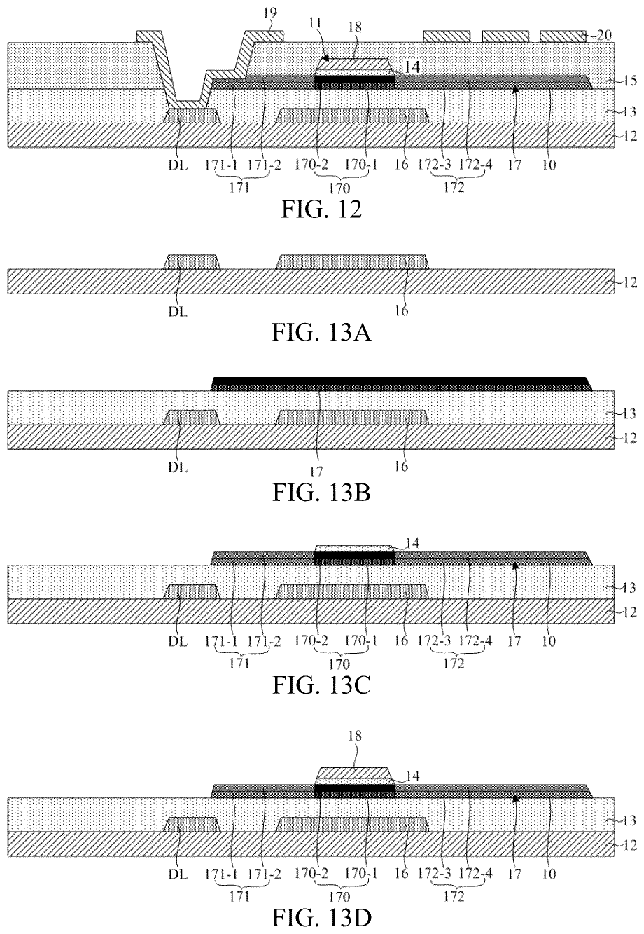

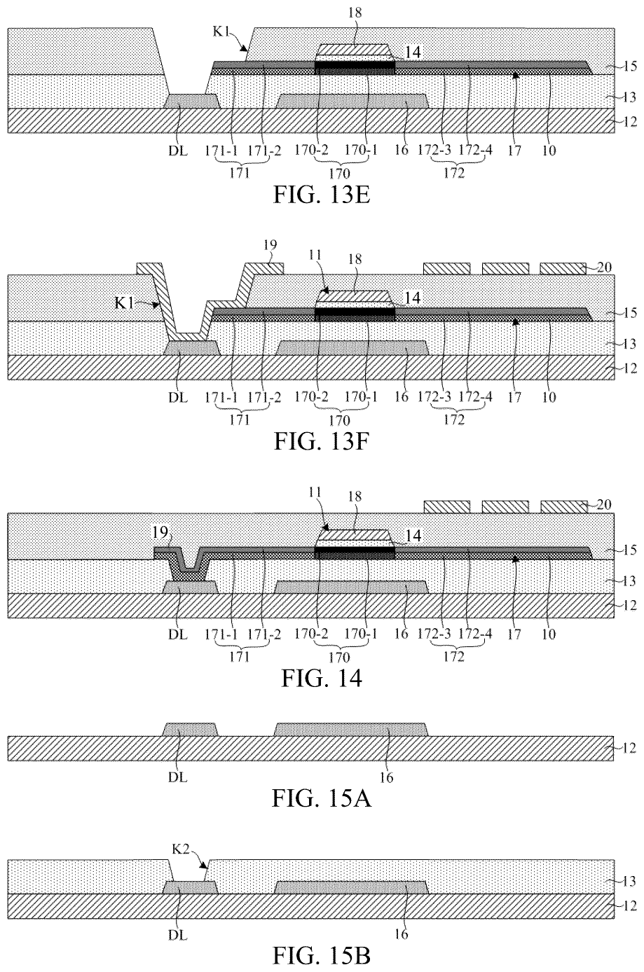

(11) Forming a pattern of a first conductive layer. Forming a pattern of a first conductive layer may include depositing a first conductive thin film on a side of a base substrate 12, and patterning the first conductive thin film by a patterning process to form a pattern of a first conductive layer located on a side of the base substrate 12. The first conductive layer may include a data line DL and a light shielding block 16, as shown in FIG. 13A.

(12) Forming a pattern of a semiconductor layer. Forming a pattern of a semiconductor layer may include: sequentially depositing a first insulation thin film and a semiconductor thin film on a side of the base substrate 12 where the aforementioned pattern is formed, and patterning the semiconductor thin film by a patterning process to form a first insulation layer 13 located on a side of the first conductive layer away from the base substrate 12 and a pattern of a semiconductor layer located on a side of the first insulation layer 13 away from the base substrate 12. The semiconductor layer may include an active layer 17 of the transistor, as shown in FIG. 13B.

As shown in FIG. 13B, an orthographic projection of the light shielding block 16 on the array substrate may include an orthographic projection of the channel region of the active layer 17 formed subsequently on the array substrate, so that light can be prevented from irradiating the channel region from a side close to the base substrate, and the influence of light on the performance of the transistor can be avoided.

(13) Forming a pattern of a second insulation layer. Forming a pattern of a second insulation layer may include: depositing a second insulation thin film on a side of the base substrate 12 where the aforementioned patterns are formed, and patterning the second insulation thin film by a patterning process to form a pattern of a second insulation layer located on a side of the semiconductor layer away from the base substrate 12, as shown in FIG. 13C.

Forming the pattern of the second insulation layer may also include performing a conductorization processing on portions of the active layer 17 using the second insulation layer 14 as a mask, so that the portions of the active layer 17 form the first region 171 and the second region 172, respectively. For example, the first region 171 may be used as a first pole of the transistor, and the second region 172 may be used as a second pole of the transistor.

As shown in FIG. 13C, the active layer 17 may include two sub-active layers. The two sub-active layers may be designated as a first sub-active layer and a second sub-active layer, respectively, and the first sub-active layer is closer to the base substrate 12 than the second sub-active layer. The channel region 170 of the active layer 17 may include a first channel region 170-1 and a second channel region 170-2. The first region 171 may include a first sub-region 171-1 and a second sub-region 171-2. The second region 172 may include a third sub-region 172-3 and a fourth sub-region 172-4. The first sub-active layer may include the first channel region 170-1 and the first sub-region 171-1 and the third sub-region 172-3 located on two opposite sides of the first channel region 170-1. The second sub-active layer may include the second channel region 170-2 and the second sub-region 171-2 and the fourth sub-region 172-4 located on two opposite sides of the second channel region 170-2.

In some exemplary embodiments, the first electrode 10 and the active layer 17 may form an integrated structure connected with each other, so that the number of film layers can be reduced and the cost of preparing the array substrate can be reduced.

(14) Forming a pattern of a second conductive layer. Forming a pattern of a second conductive layer may include: depositing a second conductive thin film on a side of the base substrate 12, and patterning the second conductive thin film by a patterning process to form a pattern of a second conductive layer located on a side of the second insulation layer 14 away from the base substrate 12. The second conductive layer may include the gate electrode 18 of the transistor, as shown in FIG. 13D.

As shown in FIG. 13D, an orthographic projection of the gate electrode 18 on the array substrate may include an orthographic projection of the channel region 170 of the active layer 17 on the array substrate, so that light can be prevented from irradiating the channel region from a side of the second conductive layer away from the base substrate 12, and light can be prevented from affecting the performance of the transistor.

(15) Forming a pattern of a third insulation layer. Forming a pattern of a third insulation layer may include: depositing a third insulation thin film on a side of the base substrate 12 where the aforementioned patterns are formed, and patterning the third insulation thin film by a patterning process of a Half Tone Mask to form a pattern of a third insulation layer located on a side of the second conductive layer away from the base substrate 12, as shown in FIG. 13E.

As shown in FIG. 13E, the third insulation layer 15 may include at least one first via K1, the first via K1 exposes a part of a surface of the first region 171 away from the base substrate 12, and exposes a part of a surface of the data line DL away from the base substrate 12, such that the connection electrode formed subsequently is connected with the first region 171 and the data line DL through the first via K1. In some exemplary embodiments, an orthographic projection of the first via K1 on the array substrate may be circular or rectangular or elliptical or polygonal or the like.

(16) Forming a pattern of a third conductive layer. Forming a pattern of a third conductive layer may include: depositing a third conductive thin film on a side of the base substrate 12, and patterning the third conductive thin film by a patterning process to form a pattern of a third conductive layer located on a side of the third insulation layer 15 away from the base substrate 12. The third conductive layer may include a connection electrode 19 and a common electrode 20, and the connection electrode 19 is connected with the first region 171 and the data line DL through the first via K1, as shown in FIG. 13F.

In some exemplary embodiments, the common electrode 20 may be a planar electrode, or the common electrode 20 may have a plurality of slits.

In some possible exemplary embodiments, the pattern of the second insulation layer and the pattern of the second conductive layer may be produced by the same patterning process.

FIG. 14 is a schematic cross-sectional view of an array substrate according to another embodiment of the present disclosure. As shown in FIG. 14, the array substrate may include a base substrate 12, and a first conductive layer, a semiconductor layer, a second conductive layer and a third conductive layer disposed on a side of the base substrate 12. The array substrate further includes a first insulation layer 13 located between the first conductive layer and the semiconductor layer, a second insulation layer 14 located between the semiconductor layer and the second conductive layer, and a third insulation layer 15 located between the second conductive layer and the third conductive layer. The first conductive layer may include a data line DL and a light shielding block 16. The semiconductor layer may include an active layer 17 of a transistor 11, and a first electrode 10 and the active layer 17 may form an integrated structure connected with each other. The second conductive layer may include a gate electrode 18 of the transistor 11, the active layer 17 may be electrically connected with the data line DL through a connection electrode 19, and the connection electrode 19 and the active layer 17 may form an integrated structure connected with each other. The third conductive layer may include a common electrode 20.

Taking the structure of the array substrate shown in FIG. 14 as an example, the preparing process of the array substrate may include the following steps.

(21) Forming a pattern of a first conductive layer. Forming a pattern of a first conductive layer may include depositing a first conductive thin film on a side of a base substrate 12, and patterning the first conductive thin film by a patterning process to form a pattern of a first conductive layer located on a side of the base substrate 12. The first conductive layer may include a data line DL and a light shielding block 16, as shown in FIG. 15A.

(22) Forming a pattern of a first insulation layer. Forming a pattern of a first insulation layer may include: depositing a first insulation thin film on a side of the base substrate 12, and patterning the first insulation thin film by a patterning process to form a pattern of a first insulation layer located on a side of the first conductive layer away from the base substrate 12.

As shown in FIG. 15B, the first insulation layer 13 may include at least one second via K2. The second via K2 exposes a part of a surface of the data line DL away from the base substrate 12, and the second via K2 is configured such that a connection electrode formed subsequently is connected with the data line DL and the active layer through the via.

(23) Forming a pattern of a semiconductor layer. Forming a pattern of a semiconductor layer may include: depositing a semiconductor thin film on a side of the base substrate 12 where the aforementioned patterns are formed, and patterning the semiconductor thin film by a patterning process to form a pattern of a semiconductor layer located on a side of the first insulation layer 13 away from the base substrate 12. The semiconductor layer may include an active layer 17 of the transistor, as shown in FIG. 15C.

(24) Forming a pattern of a second conductive layer. Forming a pattern of a second conductive layer may include: sequentially depositing a second insulation thin film and a second conductive thin film on a side of the base substrate 12, and patterning the second conductive thin film by a patterning process to form a pattern of a second insulation layer located on a side of the semiconductor layer away from the base substrate 12 and a pattern of a second conductive layer located on a side of the second insulation layer 14 away from the base substrate 12. The second conductive layer may include a gate electrode 18 of the transistor, as shown in FIG. 15D.

Forming the pattern of the second conductive layer may further include performing a conductorization processing on portions of the active layer 17 such that the portions of the active layer 17 form a first region 171 and a second region 172, respectively. For example, the first region 171 may be used as a first pole of the transistor, and the second region 172 may be used as a second pole of the transistor.

In some exemplary embodiments, as shown in FIG. 15D, the first electrode 10 and the active layer 17 may form an integrated structure connected with each other, which can reduce the number of film layers and reduce the cost of preparing the array substrate.

In some exemplary embodiments, as shown in FIG. 15D, the connection electrode 19 and the active layer 17 may form an integrated structure connected with each other, which can avoid damage to the active layer caused by the preparation of the pattern of the insulation layer, and is conducive to ensuring the performance of the transistor.

(25) Forming a pattern of a third conductive layer. Forming a pattern of a third conductive layer may include: sequentially depositing a third insulation thin film and a third conductive thin film on a side of the base substrate 12, and patterning the third conductive thin film by a patterning process to form a pattern of a third insulation layer located on a side of the second conductive layer away from the base substrate 12 and a pattern of a third conductive layer located on a side of the third insulation layer 15 away from the base substrate 12. The third conductive layer may include the common electrode 20, as shown in FIG. 15E.

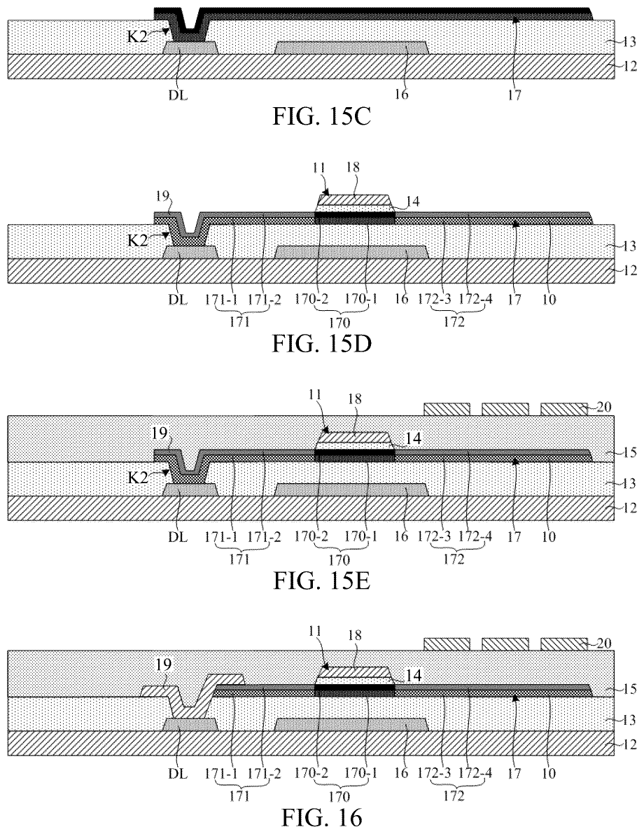

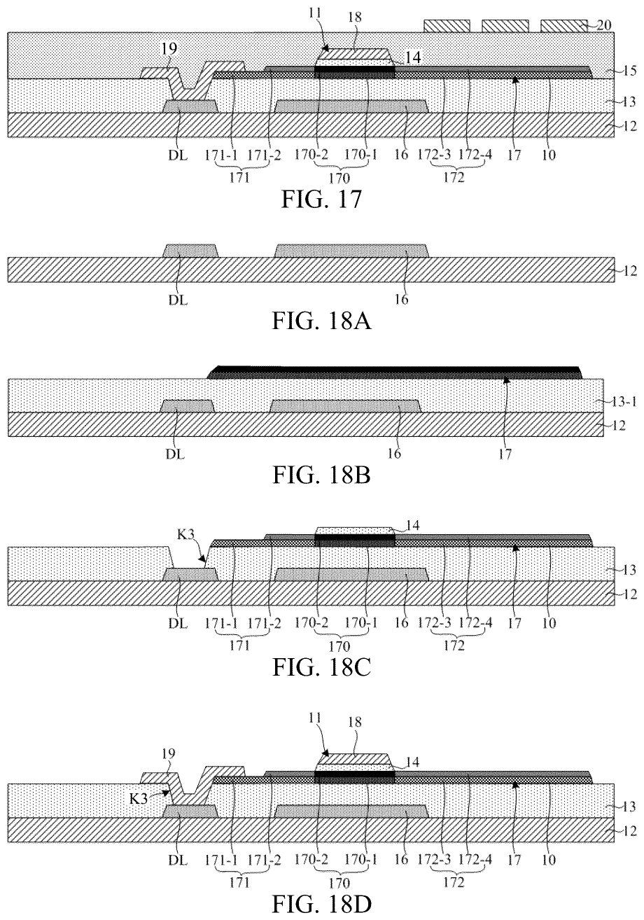

FIG. 16 is a first schematic cross-sectional view of an array substrate according to yet another embodiment of the present disclosure, and FIG. 17 is a second schematic cross-sectional view of an array substrate according to yet another embodiment of the present disclosure. As shown in FIGS. 16 and 17, the array substrate may include a base substrate 12, and a first conductive layer, a semiconductor layer, a second conductive layer and a third conductive layer disposed on a side of the base substrate 12. The array substrate further includes a first insulation layer 13 located between the first conductive layer and the semiconductor layer, a second insulation layer 14 located between the semiconductor layer and the second conductive layer, and a third insulation layer 15 located between the second conductive layer and the third conductive layer. The first conductive layer may include a data line DL and a light shielding block 16. The semiconductor layer may include an active layer 17 of a transistor 11, and a first electrode 10 and the active layer 17 may form an integrated structure connected with each other. The second conductive layer may include a gate electrode 18 of the transistor 11 and a connection electrode 19, and the active layer 17 may be electrically connected with the data line DL through the connection electrode 19. The third conductive layer may include a common electrode 20.

As shown in FIG. 17, the active layer 17 may include two or more sub-active layers. For example, the active layer 17 may include two sub-active layers, or the active layer 17 may include three sub-active layers or the like. As shown in FIG. 17, taking the active layer 17 including two sub-active layers as an example, the two sub-active layers are designated as a first sub-active layer and a second sub-active layer, respectively, and the first sub-active layer is closer to the base substrate 12 than the second sub-active layer. As shown in FIG. 17, the channel region 170 may include a first channel region 170-1 and a second channel region 170-2. The first region 171 may include a first sub-region 171-1 and a second sub-region 171-2. The second region 172 may include a third sub-region 172-3 and a fourth sub-region 172-4. The first sub-active layer may include the first channel region 170-1 and the first sub-region 171-1 and the third sub-region 172-3 located on two opposite sides of the first channel region 170-1. The second sub-active layer may include the second channel region 170-2 and the second sub-region 171-2 and the fourth sub-region 172-4 located on two opposite sides of the second channel region 170-2.

As shown in FIG. 17, an orthographic projection of the second sub-region 171-2 on the array substrate is within an orthographic projection of the first sub-region 171-1 on the array substrate, and the first sub-region 171-1 is connected with the data line DL through the connection electrode 19. In this exemplary embodiment, a part of the second sub-region 171-2 may function as a sacrificial layer during the preparation of the pattern of the second insulation layer 14, which may protect the first sub-region 171-1 from etching damage during the preparation of the pattern of the second insulation layer, may guarantee the connection reliability between the transistor and the data line DL, and may improve the yield of the array substrate.

Taking the structure of the array substrate shown in FIG. 17 as an example, the preparing process of the array substrate may include the following steps.

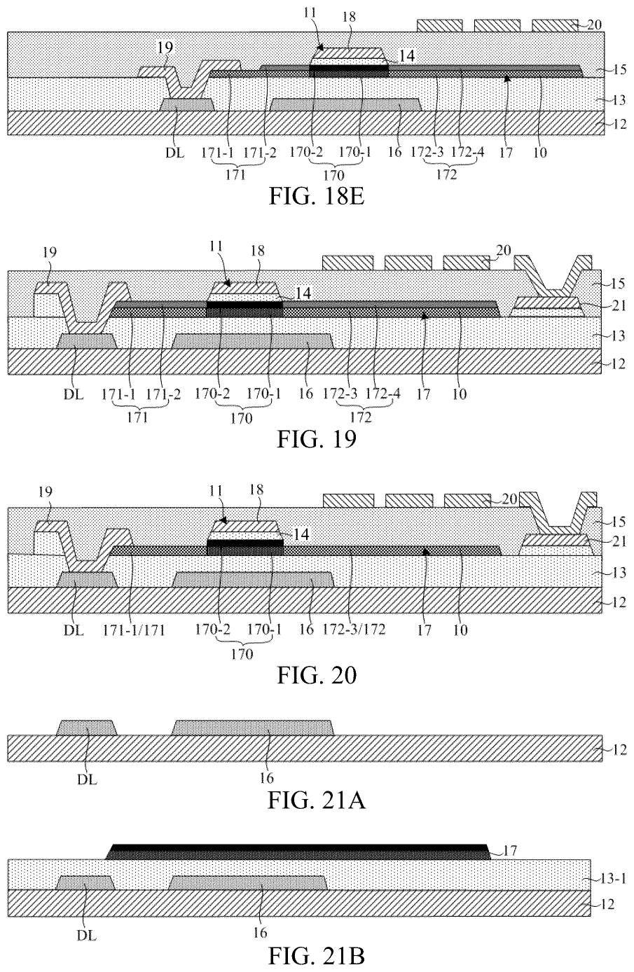

(31) Forming a pattern of a first conductive layer. Forming a pattern of a first conductive layer may include depositing a first conductive thin film on a side of a base substrate 12, and patterning the first conductive thin film by a patterning process to form a pattern of a first conductive layer located on a side of the base substrate 12. The first conductive layer may include a data line DL and a light shielding block 16, as shown in FIG. 18A.

(32) Forming a pattern of a semiconductor layer. Forming a pattern of a semiconductor layer may include: sequentially depositing a first insulation thin film 13-1 and a semiconductor thin film on a side of the base substrate 12 where the aforementioned pattern is formed, and patterning the semiconductor thin film by a patterning process to form a pattern of a semiconductor layer located on a side of the first insulation thin film 13-1 away from the base substrate 12. The semiconductor layer may include an active layer 17 of the transistor, as shown in FIG. 18B.

(33) Forming a pattern of a second insulation layer. Forming a pattern of a second insulation layer may include: depositing a second insulation thin film on a side of the base substrate 12, and patterning the second insulation thin film by a patterning process to form a pattern of a second insulation layer located on a side of the semiconductor layer away from the base substrate 12 and a pattern of a first insulation layer located on a side of the first conductive layer away from the base substrate 12.

As shown in FIG. 18C, the second insulation layer 14 may include at least one third via K3. Both the first insulation thin film and the second insulation thin film located in the third via K3 are etched away to expose a part of a surface of the data line DL away from the base substrate 12, so that a connection electrode formed subsequently is connected with the data line DL through the via.

Forming the pattern of the second insulation layer may also include performing a conductorization processing on portions of the active layer 17 using the second insulation layer 14 as a mask, so that the portions of the active layer 17 form the first region 171 and the second region 172, respectively. For example, the first region 171 may be used as a first pole of the transistor, and the second region 172 may be used as a second pole of the transistor.

As shown in FIG. 18C, the active layer 17 may include two sub-active layers. The two sub-active layers may be designated as a first sub-active layer and a second sub-active layer, respectively, and the first sub-active layer is closer to the base substrate 12 than the second sub-active layer. The channel region 170 of the active layer 17 may include a first channel region 170-1 and a second channel region 170-2. The first region 171 may include a first sub-region 171-1 and a second sub-region 171-2. The second region 172 may include a third sub-region 172-3 and a fourth sub-region 172-4. The first sub-active layer may include the first channel region 170-1 and the first sub-region 171-1 and the third sub-region 172-3 located on two opposite sides of the first channel region 170-1. The second sub-active layer may include the second channel region 170-2 and the second sub-region 171-2 and the fourth sub-region 172-4 located on two opposite sides of the second channel region 170-2.

As shown in FIG. 18C, in the process of forming the third via K3, a part of the second sub-region 171-2 is etched away to expose a part of a surface of the first sub-region 171-1 away from the base substrate 12, so that the connection electrode formed subsequently can be in contact with a part of the surface of the first sub-region 171-1 away from the base substrate 12, so as to realize the electrical connection between the connection electrode and the transistor. The electrical connection between the transistor and the data line DL can be realized through the connection electrode.

(34) Forming a pattern of a second conductive layer. Forming a pattern of a second conductive layer may include: depositing a second conductive thin film on a side of the base substrate 12, and patterning the second conductive thin film by a patterning process to form a pattern of a second conductive layer located on a side of the second insulation layer 14 away from the base substrate 12. The second conductive layer may include a connection electrode 19 and a gate electrode 18, as shown in FIG. 18D.

As shown in FIG. 18D, a part of the connection electrode 19 may be located within the third via K3, and a part of the connection electrode 19 located within the third via K3 may be connected with the data line DL. A part of the connection electrode 19 may be located on a side of the semiconductor layer away from the base substrate 12, and may be connected with a part of a surface of the first sub-region 171-1 away from the base substrate 12. The electrical connection between the transistor and the data line DL can be realized through the connection electrode 19.

(35) Forming a pattern of a third conductive layer. Forming a pattern of a third conductive layer may include: sequentially depositing a third insulation thin film and a third conductive thin film on a side of the base substrate 12, and patterning the third conductive thin film by a patterning process to form a pattern of a third insulation layer located on a side of the second conductive layer away from the base substrate 12 and a pattern of a third conductive layer located on a side of the third insulation layer 15 away from the base substrate 12. The third conductive layer may include the common electrode 20, as shown in FIG. 18E.

FIG. 19 is a third cross-sectional diagram of an array substrate according to yet another embodiment of the present disclosure. As shown in FIG. 19, the array substrate may include a base substrate 12, and a first conductive layer, a semiconductor layer, a second conductive layer and a third conductive layer disposed on a side of the base substrate 12. The array substrate further includes a first insulation layer 13 located between the first conductive layer and the semiconductor layer, a second insulation layer 14 located between the semiconductor layer and the second conductive layer, and a third insulation layer 15 located between the second conductive layer and the third conductive layer. The first conductive layer may include a data line DL and a light shielding block 16. The semiconductor layer may include an active layer 17 of a transistor 11, and a first electrode 10 and the active layer 17 may form an integrated structure connected with each other. The second conductive layer may include a gate electrode 18 of the transistor 11, a connection electrode 19, and a common electrode line 21, and the active layer 17 may be electrically connected with the data line DL through the connection electrode 19. The third conductive layer may include a common electrode 20.

As shown in FIG. 19, an orthographic projection of the connection electrode 19 on the array substrate partially overlaps with an orthographic projection of the second insulation layer 14 on the array substrate, and the second insulation layer 14 can function for planarization, so that a surface of the connection electrode 19 is substantially flush on both sides along an extension direction of the data line DL and on the side close to the base substrate 12.

FIG. 20 is a fourth schematic cross-sectional view of an array substrate according to yet another embodiment of the present disclosure. The main structure of the array substrate shown in FIG. 20 is substantially the same as the main structure of the array substrate shown in FIG. 19, except that the active layer 17 may include two sub-active layers. The two sub-active layers may be designated as a first sub-active layer and a second sub-active layer, respectively, and the first sub-active layer is closer to the base substrate 12 than the second sub-active layer. The channel region 170 of the active layer 17 may include a first channel region 170-1 and a second channel region 170-2. The first region 171 may include a first sub-region 171-1. The second region 172 may include a third sub-region 172-3. The first sub-active layer may include the first channel region 170-1 and the first sub-region 171-1 and the third sub-region 172-3 on two opposite sides of the first channel region 170-1. The second sub-active layer may include a second channel region 170-2. As shown in FIG. 20, the third sub-region 172-3 and the first electrode 10 form an integrated structure connected with each other.

In some possible embodiments, the active layer 17 may include two sub-active layers. The two sub-active layers may be designated as a first sub-active layer and a second sub-active layer, respectively, and the first sub-active layer is closer to the base substrate 12 than the second sub-active layer. The channel region 170 of the active layer 17 may include a first channel region 170-1 and a second channel region 170-2. The first region 171 may include a first sub-region 171-1. The second region 172 may include a third sub-region 172-3 and a fourth sub-region. The first sub-active layer may include the first channel region 170-1 and the first sub-region 171-1 and the third sub-region 172-3 located on two opposite sides of the first channel region 170-1. The second sub-active layer may include the second channel region 170-2 and the fourth sub-region located on a side of the second channel region 170-2. The third sub-region 172-3 and the first electrode 10 form an integrated structure connected with each other.

In some possible embodiments, an orthographic projection of the fourth sub-region on the array substrate is within an orthographic projection of the third sub-region 172-3 on the array substrate, and an area of the orthographic projection of the fourth sub-region on the array substrate is smaller than an area of the orthographic projection of the third sub-region 172-3 on the array substrate.

Taking the structure of the array substrate shown in FIG. 19 as an example, the preparing process of the array substrate may include the following steps.

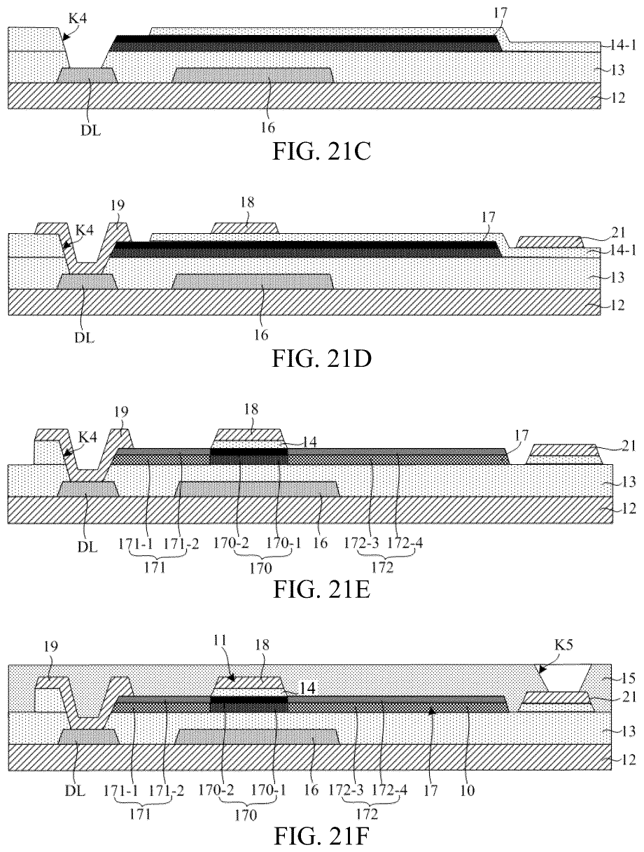

(41) Forming a pattern of a first conductive layer. Forming a pattern of a first conductive layer may include depositing a first conductive thin film on a side of a base substrate 12, and patterning the first conductive thin film by a patterning process to form a pattern of a first conductive layer located on a side of the base substrate 12. The first conductive layer may include a data line DL and a light shielding block 16, as shown in FIG. 21A.

(42) Forming a pattern of a semiconductor layer. Forming a pattern of a semiconductor layer may include: sequentially depositing a first insulation thin film 13-1 and a semiconductor thin film on a side of the base substrate 12 where the aforementioned pattern is formed, and patterning the semiconductor thin film by a patterning process to form a pattern of a semiconductor layer located on a side of the first insulation thin film 13-1 away from the base substrate 12. The semiconductor layer may include an active layer 17 of the transistor, as shown in FIG. 21B.

(43) Forming an initial pattern of a second insulation layer. Forming an initial pattern of a second insulation layer may include: depositing a second insulation thin film on a side of the base substrate 12, and patterning the second insulation thin film by a patterning process to form an initial pattern of a second insulation layer 14-1 located on a side of the semiconductor layer away from the base substrate 12 and a pattern of a first insulation layer located on a side of the first conductive layer away from the base substrate 12.

As shown in FIG. 21C, the initial pattern of the second insulation layer 14-1 may include at least one fourth via K4. Both the first insulation thin film and the second insulation thin film located in the fourth via K4 are etched away to expose a part of a surface of the data line DL away from the base substrate 12, so that a connection electrode formed subsequently is connected with the data line DL through the via.

(44) Forming a pattern of a second conductive layer. Forming a pattern of a second conductive layer may include: depositing a second conductive thin film on a side of the base substrate 12, and patterning the second conductive thin film by a patterning process to form a pattern of a second conductive layer located on a side of the initial pattern of the second insulation layer 14-1 away from the base substrate 12. The second conductive layer may include a connection electrode 19, a gate electrode 18, and a common electrode line 21, as shown in FIG. 21D.

As shown in FIG. 21D, a part of the connection electrode 19 may be located within the fourth via K4, and a part of the connection electrode 19 located within the fourth via K4 may be connected with the data line DL. A part of the connection electrode 19 may be located on a side of the semiconductor layer away from the base substrate 12, and may be connected with a part of a surface of the second sub-region formed subsequently away from the base substrate 12. The electrical connection between the transistor and the data line DL can be realized through the connection electrode 19.

(45) Forming a pattern of a second insulation layer. Forming a pattern of a second insulation layer may include: patterning the initial pattern of the second insulation layer 14-1 by a patterning process to form a pattern of a second insulation layer, as shown in FIG. 21E.

Forming the pattern of the second insulation layer may also include performing a conductorization processing on portions of the active layer 17 using the second insulation layer 14 as a mask, so that the portions of the active layer 17 form the first region 171 and the second region 172, respectively. For example, the first region 171 may be used as a first pole of the transistor, and the second region 172 may be used as a second pole of the transistor.

As shown in FIG. 21E, the active layer 17 may include two sub-active layers. The two sub-active layers may be designated as a first sub-active layer and a second sub-active layer, respectively, and the first sub-active layer is closer to the base substrate 12 than the second sub-active layer. The channel region 170 of the active layer 17 may include a first channel region 170-1 and a second channel region 170-2. The first region 171 may include a first sub-region 171-1 and a second sub-region 171-2. The second region 172 may include a third sub-region 172-3 and a fourth sub-region 172-4. The first sub-active layer may include the first channel region 170-1 and the first sub-region 171-1 and the third sub-region 172-3 located on two opposite sides of the first channel region 170-1. The second sub-active layer may include the second channel region 170-2 and the second sub-region 171-2 and the fourth sub-region 172-4 located on two opposite sides of the second channel region 170-2. In the embodiment of the present disclosure, the pattern of the second insulation layer is obtained by the two patterning processes, which can reduce the etching of the active layer by the patterning process compared with the one patterning process.

(46) Forming a pattern of a third insulation layer. Forming a pattern of a third insulation layer may include depositing a third insulation thin film on a side of the base substrate 12, and patterning the third insulation thin film by a patterning process to form a pattern of a third insulation layer located on a side of the second conductive layer away from the base substrate 12, as shown in FIG. 21F.

As shown in FIG. 21F, the third insulation layer 15 includes at least one fifth via K5, and the third insulation thin film within the fifth via K5 is etched away to expose a part of a surface of the common electrode line 21 away from the base substrate 12, so that the common electrode formed subsequently is electrically connected with the common electrode line 21 through the via.

(47) Forming a pattern of a third conductive layer. Forming a pattern of a third conductive layer may include: depositing a third conductive thin film on a side of the base substrate 12, and patterning the third conductive thin film by a patterning process to form a pattern of a third conductive layer located on a side of the third insulation layer 15 away from the base substrate 12. The third conductive layer may include the common electrode 20, as shown in FIG. 21G.

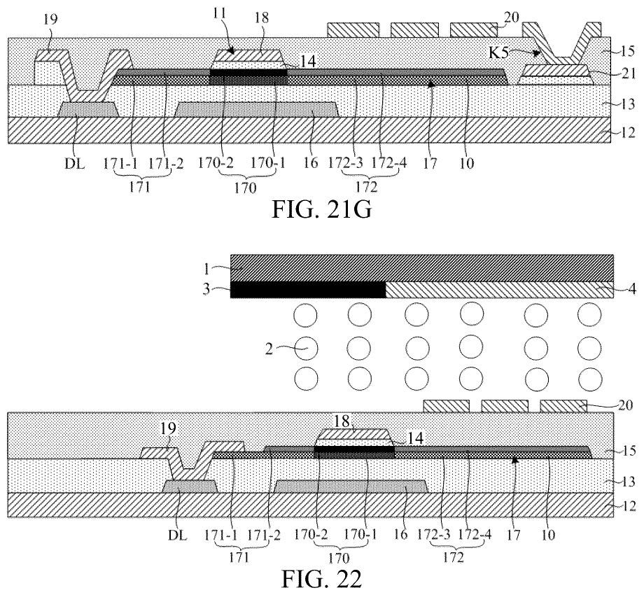

FIG. 22 is a schematic cross-sectional view of a display device according to an embodiment of the present disclosure. As shown in FIG. 22, an embodiment of the present disclosure further provides a display device. For example, illustration is made by taking an example in which the display device can implement the ADS (Advanced Super Dimension Switch) mode. The display device may include the array substrate described in any one of the foregoing embodiments.

The display device may further include an opposed substrate 1 and a liquid crystal layer 2 disposed between the array substrate and the opposed substrate 1. The first electrode and the common electrode included in the array substrate may be configured to generate an electric field that controls deflection of liquid crystal molecules in the liquid crystal layer 2. As shown in FIG. 22, the first electrode 10 and the common electrode 20 are both located on the array substrate and no electrode is disposed on the opposed substrate 1. As shown in FIG. 22, the liquid crystal molecules in the liquid crystal layer 2 may be arranged horizontally on the array substrate, and in the embodiment of the present disclosure, the horizontal direction is parallel to the plane where the array substrate is located.

In an exemplary embodiment, as shown in FIG. 22, the opposed substrate 1 may include an underlay substrate, and a black matrix 3 and a color film layer 4 disposed on the underlay substrate. However, the embodiments of the present disclosure are not limited to this.

An embodiment of the present disclosure further provides a display device. The display device includes the array substrate described in any one of the foregoing embodiments. The display device may be any product or component with a display function such as liquid crystal panel, electronic paper, a mobile phone, a tablet computer, a television, a display, a notebook computer, a digital photo frame, a navigator. However, this is not limited in the embodiments of the present disclosure.

Although the embodiments disclosed in the present disclosure are described as above, the described contents are only embodiments which are adopted in order to facilitate understanding of the present disclosure, and are not intended to limit the present disclosure. It should be noted that the above examples or embodiments are exemplary only and not restrictive. Therefore, the present disclosure is not limited to what is specifically shown and described herein. Various modifications, substitutions or omissions may be made in forms and details of implementations without departing from the scope of the present disclosure.

1. An array substrate, comprising a base substrate, and at least one transistor, at least one data line and at least one first electrode disposed on the base substrate;
wherein the at least one transistor comprises an active layer, the active layer comprises two or more sub-active layers arranged in a stack, the two or more sub-active layers comprise a first sub-active layer, the first sub-active layer is closer to the base substrate than other sub-active layers; the first sub-active layer comprises a first channel region and a first sub-region and a third sub-region located on two opposite sides of the first channel region; the data line is electrically connected with the first sub-region, and the first electrode is electrically connected with the third sub-region.

2. The array substrate according to claim 1, wherein each of the sub-active layers comprises a top surface and a bottom surface disposed oppositely, and a side surface connecting the top surface and the bottom surface, and the top surface is farther away from the base substrate than the bottom surface; and there is a slope angle between each side surface and a corresponding bottom surface; and
wherein an absolute value of a difference in slope angles of two adjacent sub-active layers is greater than or equal to 0 degree and less than or equal to 10 degrees.

3. The array substrate according to claim 2, wherein in a plane where the array substrate is located, a spacing between orthographic projection boundaries of two adjacent side surfaces is zero.

4. The array substrate according to claim 1, wherein each of the sub-active layers comprises a top surface and a bottom surface disposed oppositely, and a side surface connecting the top surface and the bottom surface; the active layer further comprises a second sub-active layer and a third sub-active layer arranged in a stack, and the third sub-active layer is farther away from the first sub-active layer than the second sub-active layer;
the first sub-active layer has a first side surface and there is a first slope angle between the first side surface and an auxiliary plane parallel to a plane where the base substrate is located, the second sub-active layer has a second side surface and there is a second slope angle between the second side surface and the auxiliary plane, and the third sub-active layer has a third side surface and there is a third slope angle between the third side surface and the auxiliary plane; and
wherein the first slope angle is the same as the third slope angle and is not the same as the second slope angle.

5. The array substrate according to claim 4, wherein the first slope angle is greater than the second slope angle.

6. The array substrate according to claim 4, wherein the first slope angle ranges from 40 degrees to 50 degrees, and the second slope angle ranges from 20 degrees to 30 degrees.

7. The array substrate according to claim 4, wherein a spacing between orthographic projection boundaries of two adjacent side surfaces on the base substrate is zero.

8. The array substrate according to claim 4, wherein a spacing between orthographic projection boundaries of at least one set of two adjacent side surfaces on the base substrate is greater than zero and less than or equal to 20 nanometers.

9. The array substrate according to claim 1, wherein the active layer comprises a top surface and a bottom surface disposed oppositely, and a side surface connecting the top surface and the bottom surface, and the top surface is farther away from the base substrate than the bottom surface; and at least a part region of the side surface is an arc surface.

10. The array substrate according to claim 1, wherein at least one parameter of two adjacent sub-active layers is different, and the parameter comprises at least one of a material, a metal doping amount, a thickness, an oxygen content, an oxygen partial pressure, and a crystalline state.

11. The array substrate according to claim 1, wherein an oxygen content of the first sub-active layer is greater than an oxygen content of a sub-active layer adjacent to the first sub-active layer.

12. The array substrate according to claim 1, wherein a material of the active layer comprises a metal oxide semiconductor material.

13. The array substrate according to claim 1, wherein a material of the sub-active layers comprises at least two of indium, gallium, and zinc elements; a doping amount of indium is greater than a doping amount of gallium, and the doping amount of indium is greater than a doping amount of zinc.

14. The array substrate according to claim 1, further comprising a first conductive layer located on a side of the base substrate, wherein the first conductive layer is located between the base substrate and the active layer; and wherein the first conductive layer comprises at least one data line.

15. The array substrate according to claim 14, further comprising a connection electrode, wherein the data line is electrically connected with the first sub-region through the connection electrode; and the connection electrode and the active layer form an integrated structure connected with each other.

16. The array substrate according to claim 14, further comprising a second conductive layer located on a side of the active layer away from the base substrate; wherein the second conductive layer comprises a gate electrode of the transistor; and
wherein the array substrate further comprises a connection electrode, the data line and the first sub-region are electrically connected through the connection electrode; and the connection electrode and the gate electrode are in a same layer structure.

17. The array substrate according to claim 14, further comprising a second conductive layer and a third conductive layer sequentially disposed and located on a side of the first conductive layer away from the base substrate; wherein the array substrate further comprises a first insulation layer located between the first conductive layer and the active layer, a second insulation layer located between the active layer and the second conductive layer, and a third insulation layer located between the second conductive layer and the third conductive layer; the third insulation layer is provided with at least one via, and the via exposes a part of a surface of the data line and the active layer; and
wherein the array substrate further comprises a connection electrode, the data line and the first sub-region are electrically connected through the connection electrode; the third conductive layer comprises the connection electrode, and a part of the connection electrode is located in the via.

18. The array substrate according to claim 1, wherein the first electrode and the active layer form an integrated structure connected with each other.

19. A display device comprising the array substrate according to claim 1, an opposed substrate, and a liquid crystal layer; wherein the array substrate is disposed opposite to the opposed substrate, and the liquid crystal layer is located between the array substrate and the opposed substrate.

20. The array substrate according to claim 2, wherein at least one parameter of two adjacent sub-active layers is different, and the parameter comprises at least one of a material, a metal doping amount, a thickness, an oxygen content, an oxygen partial pressure, and a crystalline state.
